(19) United States
(12) Patent Application Publication
(10) Pub. No.: US 2002/0121345 A1
(43) Pub. Date: Sep. 5, 2002

(54) Multi-chamber system for semiconductor process

(75) Inventors: Ching-An Chen, Hsin-Chu (TW); Hong-Ji Lee, Hsin-Chu (TW); David Guang-Kai Jeng, Hsin-Chu (TW)

Correspondence Address: Daniel R. McClure, THOMAS, KAYDEN, HORSTEMEYER & RISLEY, L.L.P., Suite 1750, 100 Galleria Parkway, N.W., Atlanta, GA, 30339-5948, US

(73) Assignee: Nano-Architect Research Corporation, Hsin-Chu (TW)

(21) Appl. No.: 09/799,158

(22) Filed: Mar. 5, 2001

(51) Int. Cl. C23C 16/505; C23F 1/02; H01L 21/3065

(52) U.S. Cl. 156/345.48; 118/719; 118/723 I; 315/111.51

(57) ABSTRACT

A multi-chamber system for processing semiconductor wafers with inductively coupled plasma comprises an inductive coil arrangement for plasma generation disposed on dielectric windows of a reaction chamber, in which the inductive coil arrangement includes a plurality of coil units in parallel to each other with a current flowing through in a direction opposite to that of adjacent coil units and a metal ring disposed above each of the coil units to meet a specific impedance. The inductive coil arrangement for plasma generation reduces the capacitive coupling between the inductive coil arrangement and the produced plasma, thereby decreasing the sheath voltage thereof and damages to the wafers during the process with the plasma. In the multi-chamber system, a plurality of working platforms are provided on a susceptor in the reaction chamber such that a plurality of small-size wafers can be simultaneously processed. The system is preferably employed with applications for simultaneously processing a plurality of small-size III-V compound semiconductors, especially suitable for etching and chemical deposition process.

### FIELD OF THE INVENTION

The present invention relates generally to equipment for the manufacture of semiconductor devices, and more particularly, to an inductive coil for plasma generation and a multi-chamber system for semiconductor process with the inductive coil. The present invention is preferably practiced in applications for simultaneously processing a plurality of III-V compound semiconductor wafers, especially suitable for their etching process and chemical deposition process.

### BACKGROUND OF THE INVENTION

Plasma-enhanced semiconductor processes for etching, deposition, resist stripped, passivation, or the like are well known. Generally, plasma may be produced from a low-pressure process gas by inducing an electron flow, which ionizes individual gas molecules through the transfer of kinetic energy through individual electron-gas molecule collisions. Most commonly, the electrons are accelerated in an electric field, such as a radio frequency (RF) electric field. Various structures have been developed to supply RF fields from devices outside of a vacuum chamber of a plasma processor to excite a gas therein to a plasma state. Inductively coupled plasma (ICP) caused by coil is one kind of such devices. One conventional apparatus is described by Jacob et al. in U.S. Pat. No. 3,705,091, in which the plasma is generated inside a low-pressure cylindrical vessel within the helical coil that is energized by 13 MHz RF radiation. This apparatus has serious contamination due to sputtering of the dielectric vessel walls caused by capacitive coupling created by the RF potentials on the coil with the vessel walls.

In U.S. Pat. No. 4,948,458, Ogle et al. describe plasma generated at a low pressure such as 0.1 milli-Torr to 5 Torr by using a spiral coil positioned on or adjacent to a planar dielectric called a window. The coil is responsive to an RF source having a frequency in the range of 1 to 100 MHz (typically 13.56 MHz), and is coupled to the RF source with an impedance matching network. According to the disclosure in U.S. Pat. No. 5,619,103 issued to Fobin, the extra dielectric acts as a means to reduce the effects of capacitive coupling between the coil and the plasma.

Recently, some researches in ICP sources have approached to process a large surface area such as 300 mm of wafer, flat panel display wafer, and liquid crystal display, etc. This is an unavoidable trend to use uniform dense plasma in ULSI or other applications for such large substrate surface. However, along with the development and requirement of high frequency and wireless communications and fiber optic communications, the present automatic transport systems and plasma reactors for etching and chemical deposition processes must be improved in order to be applied for III-V small-size wafers (e.g. 2″, 3″, 4″ and 6″) since the wafers are fragile. In consideration of the demand of III-V compound semiconductors, a manufacture system is described in the present invention.

### SUMMARY OF THE INVENTION

According to the present invention, an inductive coil arrangement for plasma generation comprises a plurality of coil units arranged in parallel to each other and a plurality of currents respectively flowing through the plurality of coil units, wherein the current flowing through each of the plurality of coil units is in a direction opposite to that of the current flowing through the adjacent coil unit. Preferably, the coil units are equally spaced from each other, and the currents flowing in each of the coil units have the same magnitude. A plurality of aluminum rings are further disposed above the coil units to meet a specific impedance, respectively, which having adjustable levelers to define the difference between ring and the coil unit. An inductive coupling plasma reactor with the inductive coil arrangement for processing semiconductors comprises a reaction chamber with the inductive coil arrangement disposed thereon, a plurality of dielectric windows respectively inserted between the coil units and the reaction chamber, a susceptor with a plurality of working platforms thereon for placing wafers in the chamber, a gas system for supply and exhaust of reaction gas into and from the reaction chamber, and a power supply for providing a bias with the susceptor.

In another embodiment of the present invention, a modified plasma generation source module comprises a multiturn coaxial helical coil, a metal ceiling above the coil, and a cylindrical metal sheet surrounding the coil. The ceiling could be a circular plate or a ring. Both of the ceiling and the cylindrical sheet are preferably made of aluminum, which surrounds the coil with a first and a second gap, respectively. For successful tuning of the matching network, a suitable impedance of the whole coil module can be achieved by adjusting the first and second gaps. The surroundings of the coil in the module can also confine and concentrate magnetic field lines resulted from current flowing through the induction coil. The single plasma source module can be flexibly combined in parallel and/or in series for further applications.

In a serial wafer transport system with improvements, a plurality of wafers can be individually positioned on a working platform by means of electrostatic attraction at the same time, thereby improving production efficiency for etch or chemical deposition processes. A multi-chamber system for processing semiconductors with high-density plasma comprises two wafer load/unload chambers for placing wafer cassettes therein, a plurality of wafer carriers each having a surface formed with a plurality of holes, each of the holes having a trench for receiving a wafer, two reaction chambers each having the inductive coil arrangement disposed thereon for plasma generation, each of the reaction chambers having a plurality of dielectric windows respectively inserted between the coil units and the reaction chamber, two wafer collection chambers each having a plurality of wafer bearers fixed to a rotary plane for holding wafers, and two wafer transport mechanisms, one connected with the wafer load/unload working chambers and wafer collection chambers, the other connected with the wafer collection chambers and reaction chambers.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 is a cross-sectional view of a modified plasma source module;

FIG. 2 is an illustration of an inductive coil arrangement for plasma generation, in which currents flow in opposite directions respectively in adjacent parallel coil units, and an adjustable aluminum ring is provided above each coil unit to meet a specific impedance;

FIG. 3 shows induced magnetic lines of force produced by currents in opposite directions;

FIG. 4 is a cross-sectional view of a plasma reactor;

FIG. 5 is a plan view of a multi-chamber system for processing semiconductor wafers with high-density plasma, in which a wafer transport system is adapted to small-size wafers;

FIG. 6 is a view to show the internal configuration in a wafer collection chamber in which six wafer bearers (three not shown), three wafer carriers, and a carrier support platform are provided;

FIG. 7 shows a wafer carrier in which six holes are provided to support wafers;

FIG. 8 is a cross-sectional view of a susceptor with electrostatic attraction function, on which six wafer working platforms are provided to process small-size wafers; and

FIG. 9 shows wafers positioned on a working platform by conveyance with a wafer carrier.

### DETAILED DESCRIPTION OF THE INVENTION

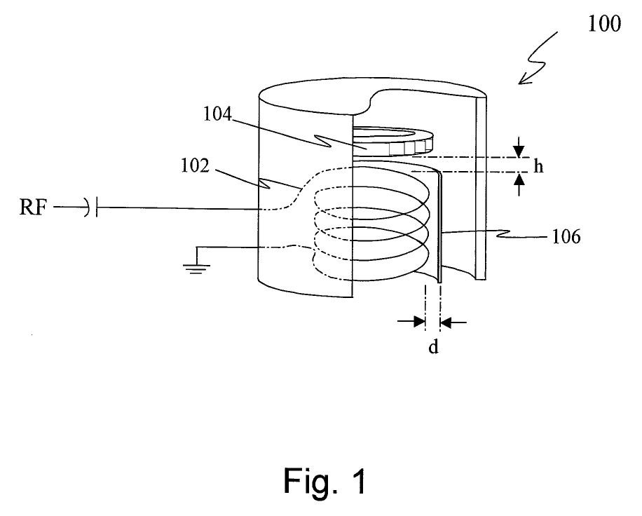

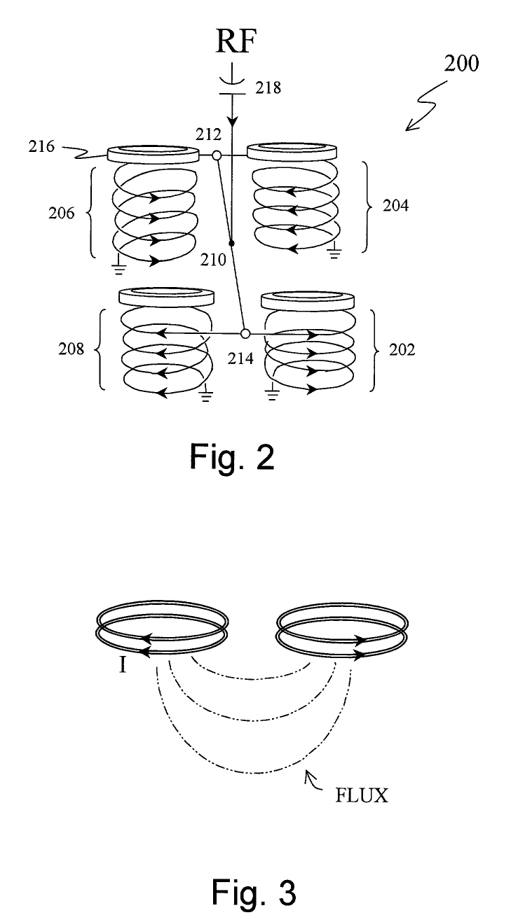

With the prior art described by Frogotson et al. [J. Vac. Sci. Technol. B14 (2), pp. 732-737, 1996], the helical-like coils are usually used to be an antenna to induce plasma via suitable RF supplier. The induction magnetic field is a function of the sum of the fields produced by each of the turns of the coil. The field produced by each of the turns is a function of the magnitude of RF current in each turn. Hence, higher induction power density and more effective reduction of capacitive coupling may be attained by using a coil with higher turn numbers. However, the matching network has limitations to tune the larger self-inductance of a multiturn coil of helical designed as disclosed by Frogotson, in which the matching network could not properly tune the larger self-inductance of three-turn 24-cm-diam helical coil formed by copper tubing with 6 mm cross sectional diameter at the 13.56 MHz drive frequency. In the first embodiment of the present invention, a modified multiturn helical coil construction managed to match with specific impedance at the 13.56 MHz drive frequency is illustrated. FIG. 1 shows a cross-sectional view of the modified plasma generation source module 100, which comprises a coaxial helical coil 102 (4-turn 24-cm-diam for instance), a metal ceiling 104 and a cylindrical metal sheet 106 surrounding the coil 102. The ceiling 104 having adjustable levelers (not shown) could be a circular plate or a ring. Both of the ceiling 104 and the cylindrical sheet 106 are preferably made of aluminum, which surrounds the coil 102 with gaps of h and d, respectively. For successful tuning of the matching network, a suitable impedance of the whole coil module 100 should be approached, and that can be achieved by adjusting the gaps of h and d. Meanwhile, the surroundings of the coil 102 in the module 100 can also confine and concentrate magnetic field lines resulted from current flowing through the induction coil 102. Single plasma source module of the present invention can be flexibly combined in parallel and/or in series for further applications. FIG. 2 shows another inductive coil arrangement for plasma generation according to the present invention, in which a coaxial helix coil arrangement 200 includes four coil units 202, 204, 206 and 208 that are connected to a common node 210 in parallel to share an individual RF power supply. Each of the coil units 202-208 is regarded as similar construction of FIG. 1, which is arranged and connected in parallel to the others and disposed on a dielectric window. A current flows from the RF power supply through the common node 210 and is divided into two currents toward nodes 212 and 214 respectively such that the currents flow in opposite directions through adjacent coil units and thus magnetic fields are induced in opposite directions by the currents. An aluminum ring 216 is disposed above each coil unit 202-208 to adjust the impedance of the coil unit 202-208, and concentrate the induced magnetic field. In one embodiment, the coil units 202-208 each is wound with four turns of a hollow copper pipe in a 3-inch diameter and has cooling water flow in the hollow copper pipe for temperature control. The diameter and turn number of the coil units depend on parameters such as operation frequency, coupling efficiency, magnetic flux, magnetic field uniformity, skin effect, impedance, oscillation parameter, parasitic capacitance, characteristics of matching system and performance index. In FIG. 2, the current provided by the RF power supply flows through a matching circuit 218 into the nodes 210, 212 and 214 and out from the ground node. The currents flow through each coil unit 202-208 in opposite direction to that of adjacent coil units such that the induced magnetic fields of adjacent coil units are out of phase and thus the induced electric fields below the coil units are almost offset. As a result, the coupling effect between the inductive coil arrangement 200 and the produced plasma is considerably reduced and the sheath voltage of the plasma is therefore reduced, thereby undesired damages to the devices processed by the plasma is decreased. FIG. 3 shows the magnetic flux lines FLUX induced by opposite currents in adjacent coils, and the similar continuous and circular magnetic flux are formed below the coil arrangement 200. The magnetic field induced by the coil arrangement 200 generates a secondary inductive current in a reaction chamber through a ceramic dielectric such that molecules are accelerated and collided to excite electrons of the molecules to produce plasma. The distance between each coil unit in the coil arrangement should be taken care to avoid undesired dissipation effect between the RF electromagnetic fields induced by the respective coil units. For instance, the distance between the centers of two coil units is about 4.5 inches for processing 8-inch wafers. To cope with large semiconductor wafers, a plurality of the coil arrangement 200 shown in FIG. 2 can be readily combined to form a desired plasma source.

As described above, the inductive coil arrangement of the present invention can be applied in a semiconductor manufacture process, and more particularly, in etch and chemical deposition processes for III-V compound semiconductors. It will be explained below how to use such a coil arrangement to form an inductive coupling plasma system.

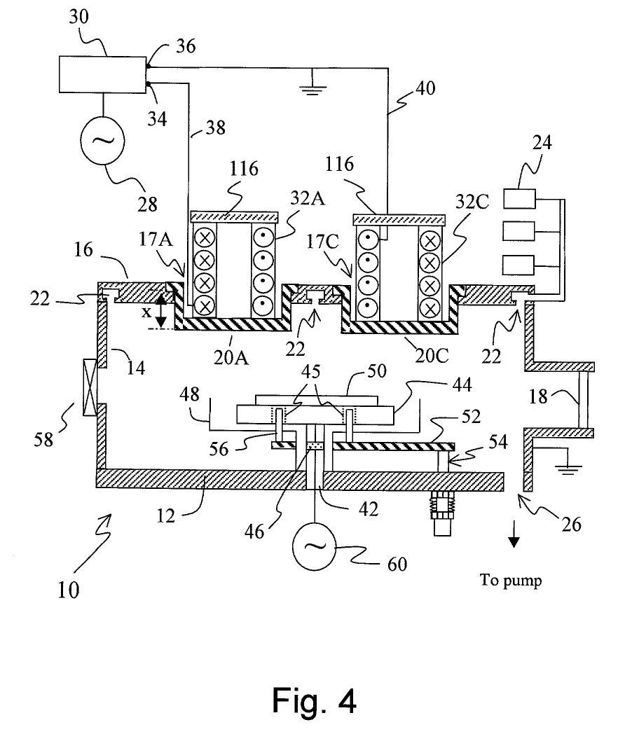

An inductively coupled plasma reactor is shown in FIG. 4, in which a vacuum reactor body 10 comprises a bottom 12 made of stainless steel, a chamber wall 14, a flange 16 and a glass viewing window 18. In correspondence to the coil units, four trenches 17A-D with a same diameter are formed on the flange 16 to be placed with small dielectric windows 20A-D on them. The dielectric windows 20A-D are preferably made of aluminum oxide or quartz. For the purpose of low power and high etching rate, the dielectric windows 20A-D each is formed of a disc shape, and coil units 32A-D each is disposed on a respective disc. The disc-shaped dielectric windows 20A-D each is deeply into the reaction chamber 10 at a distance x, where x is between 0 cm and 10 cm, in this embodiment, preferably between 0 cm and 5 cm. Meanwhile, in consideration of distribution of reaction gas introduced into the reaction chamber 10, nozzles 22 are mounted on the flange 16 around the trenches 17A-D. To avoid undesired induced heat dissipation, the flange 16 is made of a non-permeable metal such as anodized aluminum. The above vacuum components are combined together by welding, gaskets, O-ring and helical joints.

The reaction gas is supplied from gas containers 24 through the nozzles 22 into the reaction chamber 10, and then is excited to produce plasma. A vacuum pipeline 26 of the reactor 10 is connected to a vacuum pump and the pressure in the reaction chamber 10 is maintained in a range of from 1×10⁻⁶ Torr to 1 Torr, preferably, from 1×10⁻⁴ Torr to 1×10⁻¹ Torr. In such a pressure range, the apparatus can produce plasma with a high ion density and an excellent anisotropic etching. The plasma generation system employs also an RF power supply 28, a matching network 30 in addition to the inductive coil arrangement 32 that includes four coaxial helical coil units 32A-D each wound in a 3-inch diameter with a 3/16-inch diameter copper pipe. The coil units 32A-D centrally spaced about 4.5 inches can applied to process 8-inch wafers. Aluminum rings 116 are disposed respectively on each of the coil units 32A-D to adjust their impedance. It should be noted that the coil arrangement of the present invention could easily increase the turn number of each coil unit and change the number of coil units, and the diameter and shape of each coil unit adaptively to wafer size.

The resultant coil arrangement 32 is placed on the dielectric windows 20A-D with a matching network 30 coupled to the RF power supply 28, in which the matching network 30 includes an output terminal 34 connected to a line 38 to supply the desired power and an input terminal 36 connected to ground through a line 40. The RF power supply uses the ISM standard frequency of 13.56 MHz, 27.12 MHz or 40.68 MHz, typically 13.56 MHz.

Below the ceramic dielectric windows 20A-D in the reaction chamber 10, a susceptor 44 is provided in connection with the bottom 12 by a support pillar 42 that is inserted with a ceramic isolation 46 in the middle to prevent the bias for the susceptor 44 from dissipation. An RF shield 48 is concentrically surrounding the susceptor 44. The distance between wafers 50 and the bottom of the dielectric windows 20A-D ranges from 5 cm to 10 cm, which will influence the efficiency of the plasma process. Below the susceptor 44 is provided an elevating ring 52 that is movable in the vertical direction under control of an actuator with four ceramic pins 56 fixed on the elevating ring 52 and movable along with the elevating ring 52 in four channels 45 passing through the susceptor 44. The pins 56 support the wafers 50 when the wafers 50 are delivered to the susceptor 44 by a robot through a vacuum valve 58 such that the wafers 50 can be smoothly and slowly placed on the susceptor 44. An RF generator 60 of the ISM standard frequency 13.56 MHz as the RF generator 28 provides the bias for the susceptor 44. However, power supplies of frequencies between kHz and MHz can be used alternately. Moreover, an electrostatic chuck apparatus can be provided on the susceptor 44 so that the wafers 50 can uniformly and completely contact with the susceptor 44 to maintain a constant temperature on the surface of the wafers 50. In general, helium passes by the back of the wafers 50 for helium is a good thermally conductive gas.

The plasma system of the present invention is adapted to the semiconductor etch and chemical deposition processes, especially to the etching process for IC devices sensitive to ion bombardment. In the development, the III-V compound semiconductor wafer is restricted by the difficulty in growth of multiple elements, the available wafer therefore stand still in small size, such as 2 inches, 3 inches, 4 inches and 6 inches, and typically practiced with 2 inches and 3 inches. In contrast, silicon wafer is enlarged to 12 inches due to their fast development and flexibility. On the market demand, most of the current semiconductor manufacture machines are directed to silicon wafers, and seldom are designed for III-V compound wafers. However, along with development of wireless and high frequency communications, machines for efficient manufacture of III-V compound semiconductors are desired.

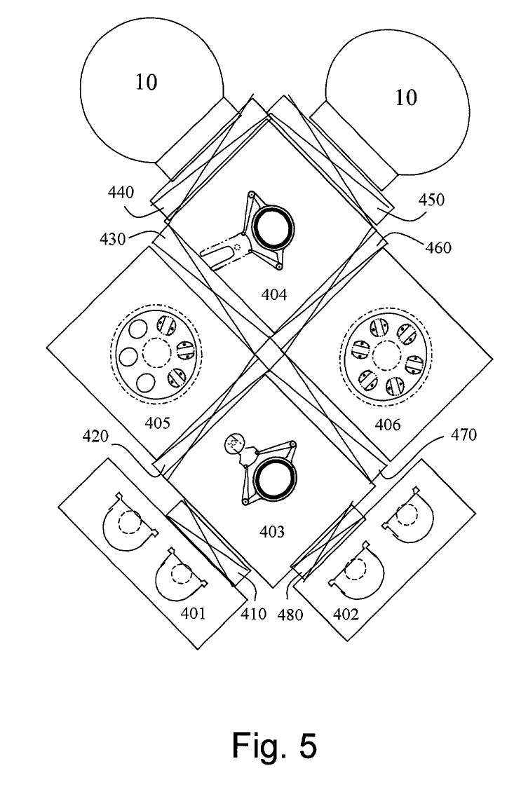

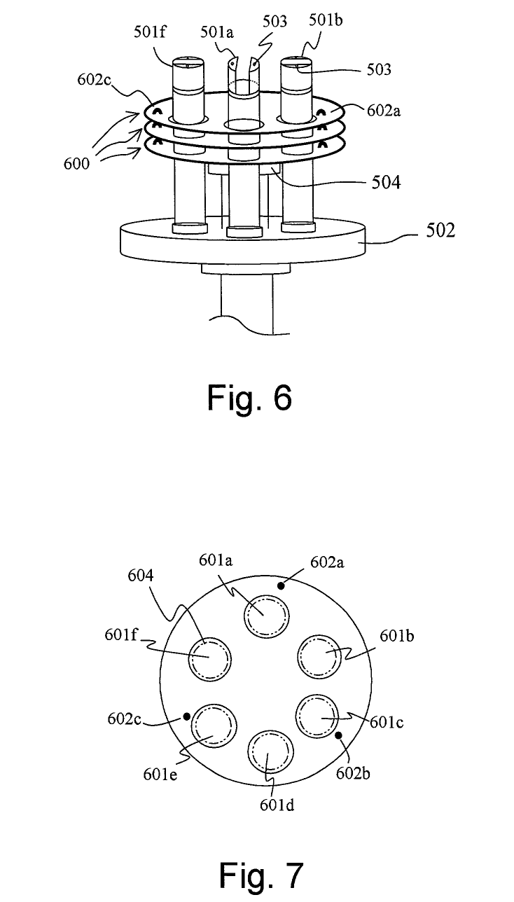

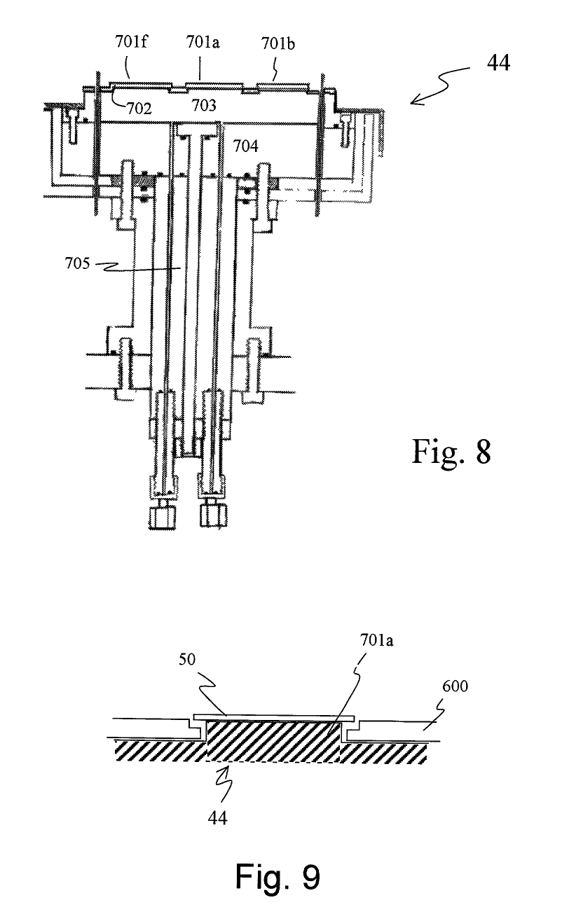

FIG. 5 is a plan view of an automatic mechanism for etching process. Numerals 401 and 402 represent small-size wafer load/unload chambers (2″ for instance) in each of which at least two wafer cassettes are provided. Numerals 403 and 404 represent wafer transport mechanisms in each of them a robot movable in the vertical direction, rotatable and expandable to convey wafers and wafer carriers is mounted. Vacuum attraction holes are provided on the robots to carry wafers or wafer carrier 600. Numerals 405 and 406 represent wafer collection chambers in each of them six wafer bearers 501a-f as shown in FIG. 6 for 2-inch wafers are contained. Each of the wafer bearers 501a-f is composed of two arc-shaped aluminum pieces with a gap therebetween to allow the robot of the wafer transport mechanism 403 to vertically move therethrough. These six bearers 501a-f are fixed at bottom onto a rotary plane 502 with 60 degrees in each rotation under control of an actuator. When one bearer receives a wafer from the robot of the wafer transport mechanism 403, the rotary plane 502 is rotated for the next bearer ready to receive another wafer from the robot. A vacuum chuck hole 503 is provided on top of each of the bearers 501a-f to hold a wafer by pressure difference to prevent the wafer from slipping in the rotation. A carrier support platform 504 movable in the vertical direction is further mounted in the center between the bearers 501a-f to elevate the wafer carrier 600 to a fixed position for the robot of the wafer transport mechanism to fetch the wafer carrier 600. The carrier support platform 504 rotates with the rotary plane 502. As shown in FIG. 7, the wafer carrier 600 has six holes 601a-f with a support trench 604 in each hole 601a-f and three arc-shaped projections 602a-c formed on the surface of the wafer carrier 600. Before etching, the wafer carrier 600 is placed in the working chamber 405 and stacked on the platform 504 passing through the bearers 501a-f. The stacked wafer carriers 600 are separated by the projections 602a-602c with a gap therebetween for the robot to move in and out to hold the wafer carrier 600 up and down. As shown in FIG. 8, six working platforms 701a-f for small-size wafers are provided on the susceptor 44 in the reaction chamber 10 in correspondence to the holes 601a-f of the wafer carrier 600. Each one of the working platforms 701a-f has a diameter slightly smaller than that of the holes 601a-f and the structure to provide electrostatic attraction and bias employed with an aluminum oxide dielectric layer 702, an aluminum electrode 703, an aluminum disc 704 to provide channels for cooling water and thermally conductive gas, and a copper tube 705 for DC and RF power supply. The wafer carrier 600 loaded with the wafers 50 thereon is conveyed to above the susceptor 44 by the robot, and then is landed slowly on the susceptor 44 by the four lift pins 56. When the wafer carrier 600 is placed on the susceptor 44, the wafers 50 on the wafer carrier 600 are positioned on the working platforms 701a-f as shown in FIG. 9.

The etching process is carried out in a low-pressure condition as followed procedures. The valves 410 and 420 between the working chambers 401 and 403 and between the working chambers 403 and 405 are opened. The robot of the wafer transport mechanism 403 takes a wafer from the cassette and delivers it to the bearer 501a. After the wafer is positioned, the plane 502 is rotated in clockwise by 60 degrees by a motor such that the bearer 501b faces a second wafer delivered by the robot. Then the second wafer is placed on the bearer 501b by the robot. The above procedure is repeated until all wafers to be processed are collected on the bearers 501. The valves 410 and 420 are closed and the valve 430 is opened. The robot of the wafer transport mechanism 404 moves into the wafer collection chamber 405 to elevate the wafer carrier 600 until it leaves the bearers 501. At this time, six wafers 50 are positioned in the trenches 604 and then sent to the reaction chamber 10 by the robot. The vacuum valve 430 is closed, and the vacuum valve 440 is opened. The wafer carrier 600 is delivered to above the susceptor 44 and the pins 56 are moved upwardly to receive the wafer carrier 600 for the robot to retract back. The vacuum valve 440 is closed, and the pins 56 are lowered slowly until the wafer carrier 600 is stably placed on the susceptor 44 such that the respective wafers 50 are properly positioned on the working platforms 701. A DC power supply is turned on for the wafers 50 to closely contact with the working platforms 701 by electrostatic effect on the susceptor 44 in order that good thermal conduction between the wafers 50 and the working platforms 701 is obtained. Cooling water and thermally conductive helium are provided below the susceptor 44 to maintain the temperature on the surfaces of the wafers 50. The system employs two reaction chambers 10 to simultaneously process wafers to increase throughput. After the wafers 50 are processed, they are collected back into the cassette in the working chamber 402 in a reverse procedure. After several rounds of the above steps, the wafer carriers 600 in the wafer collection chamber 405 have been transferred into another wafer collection chamber 406. The above procedure is repeated so that only load/unload of the cassette is needed, instead of mounting additional wafer carriers or opening up the vacuum state of the whole system.

The plasma system of the present invention is suitable for etch and chemical deposition processes for semiconductor wafers, especially for small-size III-V compound semiconductors. In addition to the etch process chamber described above, chemical deposition chamber, thermal treatment chamber and metal sputtering process chamber can be optionally employed in the system.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. An inductive coupling plasma reactor for processing semiconductors comprising:
a reaction chamber having a bottom, a top cover and a surrounding side;
an inductive coil arrangement disposed on the top cover for plasma generation, the inductive coil arrangement including a plurality of coil units in parallel to each other with a plurality of currents respectively flowing through the plurality of coil units, wherein the current flowing through each of the plurality of coil units is in a direction opposite to that of the current flowing through the adjacent coil unit;
a plurality of dielectric windows respectively inserted between the plurality of coil units and the reaction chamber;
a susceptor connected with the bottom through a support rod;
a gas system connected to the reaction chamber for supply and exhaust of a reaction gas; and
a power supply connected with the susceptor for providing a bias.

2. The reactor according to claim 1, wherein the top cover is a flange on which a plurality of trenches are formed into the reaction chamber with a distance for disposing the plurality of coil units thereon.

3. The reactor according to claim 2, wherein the distance is between 0 cm and 10 cm.

4. The reactor according to claim 3, wherein the distance is between 0 cm and 5 cm.

5. The reactor according to claim 1, wherein the plurality of dielectric windows are formed of aluminum oxide, quartz or other ceramics.

6. The reactor according to claim 1, wherein the plurality of dielectric windows each is formed of a disc shape.

7. The reactor according to claim 1, further comprising a plurality of aluminum rings respectively disposed above the plurality of coil units.

8. The reactor according to claim 1, wherein the susceptor is spaced from the plurality of dielectric windows with a distance in a range of from 5 cm to 10 cm.

9. The reactor according to claim 1, wherein the susceptor comprises a plurality of working platforms for respectively providing a wafer to be placed on.

10. A multi-chamber system for processing semiconductors with high-density plasma comprising:
a first and a second wafer load/unload chambers for placing a plurality of wafer cassettes therein;
a plurality of wafer carriers each having a surface formed with a plurality of holes, each of the plurality of holes having a trench for receiving a wafer;
a first and a second reaction chambers each having an inductive coil arrangement disposed thereon for plasma generation, the inductive coil arrangement including a plurality of coil units in parallel to each other with a plurality of currents respectively flowing through the plurality of coil units, wherein the current flowing through each of the plurality of coil units is in a direction opposite to that of the current flowing through the adjacent coil unit, each of the reaction chambers having a plurality of dielectric windows respectively inserted between the plurality of coil units and the reaction chamber and a susceptor having a surface formed thereon with a plurality of working platforms corresponding to the plurality of holes, each of the plurality of working platforms having a diameter smaller than that of the plurality of holes;
a first and a second wafer collection chambers each having a plurality of wafer bearers fixed to a rotary plane, each of the plurality of wafer bearers mounted with a vacuum suction hole thereon for holding a wafer, and a wafer carrier support platform mounted between the plurality of wafer bearers in rotation with the rotary plane; and
a first and a second wafer transport mechanisms, the first wafer transport mechanism respectively connected with the first and second wafer load/unload working chambers and the first and second wafer collection chambers, the second wafer transport mechanism respectively connected with the first and second wafer collection chambers and the first and second reaction chambers.

11. The system according to claim 10, further comprising a plurality of aluminum rings respectively disposed above the plurality of coil units.

12. The system according to claim 10, wherein around the surface of each of the wafer carriers is formed with a plurality of arc-shaped projections.

13. The system according to claim 10, wherein each of the plurality of wafer bearers comprises two arc-shaped aluminum pieces with a gap therebetween.

14. The system according to claim 10, further comprising:
a first and a second vacuum valves respectively between the first wafer transport mechanism and the first and second wafer load/unload working chambers;
a third and a fourth vacuum valves respectively between the first wafer transport mechanism and the first and second wafer collection chambers;
a fifth and a sixth vacuum valves respectively between the second wafer transport mechanism and the first and second wafer collection chambers; and
a seventh and an eighth vacuum valves respectively between the second wafer transport mechanism and the first and second reaction chambers.

15. The system according to claim 10, wherein the plurality of wafer carriers are stacked on the support platform by passing through the plurality of bearers.

16. The system according to claim 10, wherein the first wafer transport mechanism fetches wafers from the first wafer load/unload working chamber and delivers them to the first wafer collection chamber, the second wafer transport mechanism fetches the wafers from the first wafer collection chamber and delivers them to the first and second reaction chambers for being processed, and the processed wafers are delivered to the second wafer collection chamber by the second wafer transport mechanism and sent to the second wafer load/unload working chamber by the first wafer transport mechanism.

17. A modified plasma generation source module comprising:
a multiturn coaxial helical coil;
a metal ceiling spaced above the coil with a first gap; and
a cylindrical metal sheet surrounding the coil with a second gap therebetween.

18. The module according to claim 17, wherein both of the ceiling and the cylindrical sheet are made of aluminum.

19. The module according to claim 17, wherein the ceiling is a circular plate or a ring.

20. An inductive coil arrangement for plasma generation comprising:
a plurality of coil units arranged in parallel to each other;
a plurality of aluminum rings respectively disposed above the plurality of coil units; and
a plurality of currents respectively flowing through the plurality of coil units;
wherein the current flowing through each of the plurality of coil units is in a direction opposite to that of the current flowing through the adjacent coil unit.

21. The inductive coil arrangement according to claim 20, wherein the plurality of coil units are equally spaced from each other.

22. The inductive coil arrangement according to claim 20, wherein the plurality of currents have the same magnitude.

23. The inductive coil arrangement according to claim 20, wherein the plurality of aluminum rings have adjustable levelers to define the difference between ring and the top of the coil.
